(19) United States
(12) Patent Application Publication
(10) Pub. No.: US 2005/0023568 A1
(43) Pub. Date: Feb. 3, 2005

(54) Semiconductor integrated circuit device

(76) Inventor: Hidetaka Nishimura, Gifu-shi (JP)

Correspondence Address: SHERIDAN ROSS PC, 1560 BROADWAY, SUITE 1200, DENVER, CO, 80202, US

(21) Appl. No.: 10/903,596

(22) Filed: Jul. 29, 2004

(30) Foreign Application Priority Data
Aug. 1, 2003 (JP) 2003-285158

(51) Int. Cl. H01L 27/10

(52) U.S. Cl. 257/211

(57) ABSTRACT

A semiconductor integrated circuit device including dummy conductive pieces for flattening a wiring layer, while reducing parasitic capacitance produced between wires by the dummy conductive pieces. The device includes a semiconductor substrate. The wires are formed on the semiconductor substrate with a predetermined distance therebetween. The dummy conductive pieces are formed between the wires. Each dummy conductive piece is shaped to reduce capacitance between the dummy conductive piece and an adjacent one of the wires.

### CROSS-REFERENCE TO RELATED APPLICATIONS

This application is based upon and claims priority from Japanese Patent Application No. 2003-285158 filed on Aug. 1, 2003, the contents of which is herein incorporated in its entirety by reference.

### BACKGROUND OF THE INVENTION

The present invention relates to a semiconductor integrated circuit device having a multilayer wiring configuration in which plural layers of wires are configured on a semiconductor substrate, and more particularly, to a semiconductor integrated circuit device having a wiring layer including dummy conductive pieces, formed from the same material as the wires, to flatten the wiring layer.

A multilayer wiring configuration in which plural layers of wires are configured on a semiconductor substrate is known in the prior art as a configuration for increasing the integration of a semiconductor integrated circuit device. In a semiconductor circuit device having a multilayer wiring configuration, when a wiring layer includes a high wire density section and a low wire density section, a stepped portion is formed in an insulation film, which is applied to the wiring layer. As a result, wire breakage may occur in a layer formed on the insulation layer. This would decrease the wiring reliability.

To solve this problem, in the prior art, dummy conductive pieces, which are not connected to any wire, are formed in sections where the interval between wires is large. This prevents the formation of a stepped portion. FIGS. 1A and 1B are schematic diagrams showing an example of a semiconductor integrated circuit device having dummy conductive pieces. FIG. 1A is a schematic plan view showing the configuration of part of the semiconductor integrated circuit device. FIG. 1B is a cross-sectional view taken along line 1B-1B in FIG. 1A.

As shown in FIG. 1B, the semiconductor integrated circuit device includes a semiconductor substrate 10, an insulation film 20 formed on the semiconductor substrate 10, a first wiring layer 30 formed on the insulation film 20, an interlayer insulation film layer 40 covering the first wiring layer 30, and a second wiring layer 50 formed on the interlayer insulation film layer 40.

Referring to FIGS. 1A and 1B, wires 30a and 30b, which are made of aluminum, are formed in the first wiring layer 30. Photolithography, which is known in the art, is performed to form box-shaped dummy conductive pieces 30D between the wires 30a and 30b. The dummy conductive pieces 30D are made of the same material as the wires 30a and 30b. More specifically, the wires 30a and 30b are generally parallel to each other. The dummy conductive pieces 30D each have sides that are parallel to the wires 30a and 30b. Further, the dummy conductive pieces 30D are formed at generally equal intervals in a direction parallel to the wires 30a and 30b, or in a vertical direction as viewed in FIG. 1A, and are slightly deviated from one another in a direction perpendicular to the wires 30a and 30b, or in a horizontal direction as viewed in FIG. 1A.

The interlayer insulation film layer 40 includes an interlayer insulation film 40a, which is formed from a plasma-tetra-ethoxy-silane (p-TEOS) film, an interlayer insulation film 40b, which has superior flatness and is formed from a spin-on glass (SOG) film on the interlayer insulation film 40a, and an interlayer insulation film 40c, which is formed from a p-TEOS film on the interlayer insulation film 40b. The second wiring layer 50, which includes a wire 50a made of aluminum, is formed on the interlayer insulation film 40c.

In this manner, the dummy conductive pieces 30D fill the gaps formed between the wires 30a and 30b so that the upper surface of the interlayer insulation film 40c is flat when the interlayer insulation films 40a to 40c are formed on the first wiring layer 30. Subsequent to the formation of the interlayer insulation films 40a to 40c, when the interlayer insulation film 40c is further flattened by performing, for example, chemical mechanical polishing (CMP), the dummy conductive pieces 30D reduce local concentration of load. Thus, the dummy conductive pieces 30D prevent the flatness from decreasing due to load concentration. The increase in the flatness of the interlayer insulation film 40c, which is the base of the second wiring layer 50, suppresses the occurrence of wire breakage.

Japanese Laid-Open Patent Publication No. 10-335326 describes such a semiconductor integrated circuit device. The device includes linear dummy metals (dummy conductive pieces) that are parallel to adjacent wires.

The formation of the dummy conductive patterns 30D solves the problem of wire breakage. However, opposing capacitance, or parasitic capacitance, is produced between the wires 30a and 30b by the dummy conductive pieces. Parasitic capacitance decreases the operation speed of the circuit and increases noise. This affects the circuit characteristics of the semiconductor integrated circuit device in an undesirable manner.

### SUMMARY OF THE INVENTION

The present invention provides a semiconductor integrated circuit device that includes dummy conductive pieces, which flatten the wiring layer, while reducing parasitic capacitance produced between wires by the dummy conductive pieces.

One aspect of the present invention is a semiconductor integrated circuit device including a semiconductor substrate. A plurality of wires are formed on the semiconductor substrate with a predetermined distance therebetween. A dummy conductive piece is formed between the wires, with the dummy conductive piece shaped to reduce capacitance produced between the dummy conductive piece and an adjacent one of the wires.

Another aspect of the present invention is a semiconductor integrated circuit device including a side surface formed when cut out as a chip. The device includes a semiconductor substrate. A plurality of wires are formed on the semiconductor substrate with a predetermined distance therebetween. A dummy conductive piece is formed between the wires, with the dummy conductive piece being box-shaped and including four sides that are not parallel to the side surface of the semiconductor substrate.

A further aspect of the present invention is a semiconductor integrated circuit device including a semiconductor substrate. A plurality of wires are formed on the semiconductor substrate with a predetermined distance therebetween. A plurality of dummy conductive pieces are formed between the wires, with the dummy conductive pieces being polygonal prisms including opposing sides. The distance between the opposing sides changes intermittently or continuously.

A further aspect of the present invention is a semiconductor integrated circuit device including a semiconductor substrate. A plurality of wires are formed on the semiconductor substrate with a predetermined distance therebetween. A dummy conductive piece is formed between the wires, with the dummy conductive piece being cylindrical.

A further aspect of the present invention is a semiconductor integrated circuit device including a semiconductor substrate. A plurality of wires are formed on the semiconductor substrate with a predetermined distance therebetween. A dummy conductive piece is formed between the wires. The dummy conductive piece is a polygonal prism including a plurality of sides. The side closest to one of the wires is not parallel to the one of the wires.

A further aspect of the present invention is a semiconductor integrated circuit device including a semiconductor substrate. A plurality of wires are formed on the semiconductor substrate with a predetermined distance therebetween. A dummy conductive piece is formed between the wires, with the dummy conductive piece being shaped so that a portion opposing an adjacent one of the wires has a reduced area.

A further aspect of the present invention is a semiconductor integrated circuit device including a semiconductor substrate. A plurality of first wires are formed on the semiconductor substrate with a predetermined distance therebetween. A dummy conductive piece is formed between the first wires. An insulation film covers the first wires and the dummy conductive piece. A plurality of second wires are formed on the insulation film, with the dummy conductive piece shaped to reduce capacitance between the dummy conductive piece and an adjacent one of the second wires.

A further aspect of the present invention is a semiconductor integrated circuit device including a semiconductor substrate. A plurality of first wires are formed on the semiconductor substrate with a predetermined distance therebetween. A dummy conductive piece is formed between the first wires. An insulation film covers the first wires and the dummy conductive piece. A plurality of second wires are formed on the insulation film, with the dummy conductive piece being shaped so that a portion opposing an adjacent one of the second wires has a reduced area.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1A is a plan view showing a semiconductor integrated circuit device of the prior art;

FIG. 1B is a cross-sectional view taken along line 1B-1B in FIG. 1A;

FIG. 2A is a plan view showing a semiconductor integrated circuit device according to a preferred embodiment of the present invention;

FIG. 2B is a cross-sectional view taken along line 2B-2B in FIG. 2A;

FIG. 3 is a perspective view showing the outer appearance of a dummy conductive piece of FIG. 2A;

FIG. 4 is a plan view showing a layout example of a wiring layer in the semiconductor integrated circuit device of FIG. 2A; and

FIGS. 5A to 5L are plan views showing further modifications of the dummy conductive pieces used in the preferred embodiment of the present invention.

### DETAILED DESCRIPTION OF THE PREFERRED EMBODIMENTS

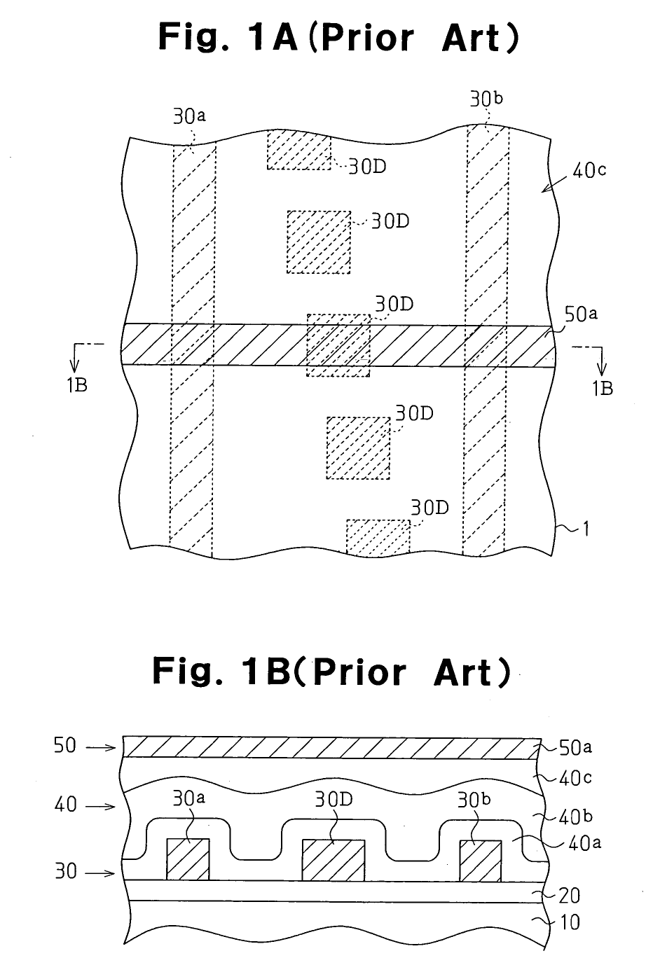

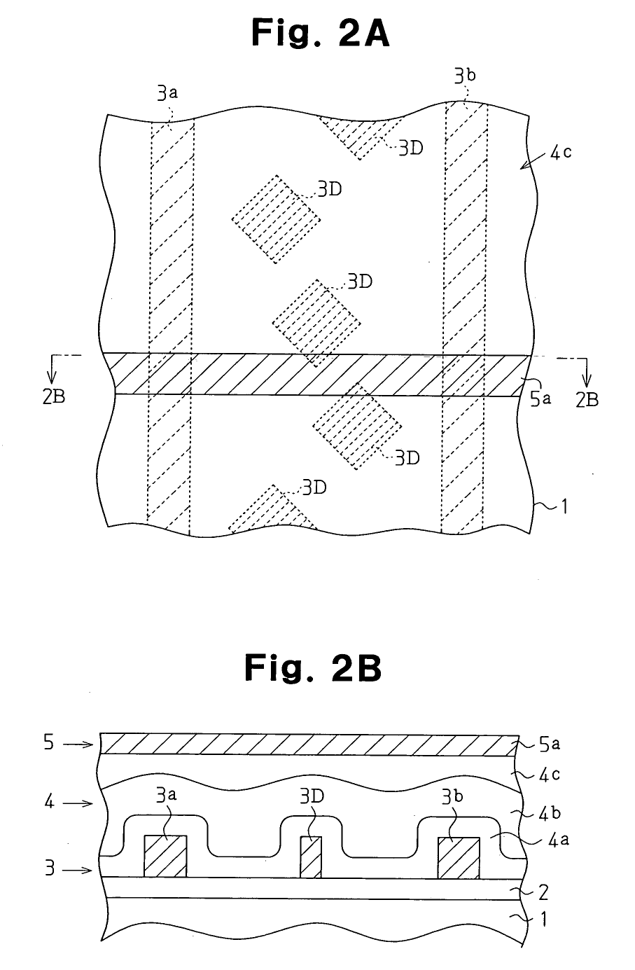

FIGS. 2A and 2B schematically show a semiconductor integrated circuit device according to a preferred embodiment of the present invention. In the same manner as the semiconductor integrated circuit device shown in FIGS. 1A and 1B, dummy conductive pieces are formed to flatten the base of an upper wiring layer in the semiconductor integrated circuit device. However, in the semiconductor integrated circuit device of FIGS. 2A and 2B, the layout of the dummy conductive pieces decreases the opposing capacitance (parasitic capacitance) produced between adjacent wires through the dummy conductive pieces.

FIG. 2A is a schematic plan view showing the configuration of part of the semiconductor integrated circuit device. FIG. 2B is a cross-sectional view taken along line 2B-2B in FIG. 2A.

As shown in FIG. 2B, the semiconductor integrated circuit device of the preferred embodiment includes a semiconductor substrate 1, an insulation film 2 formed on the semiconductor substrate 1, a first wiring layer 3 formed on the insulation film 2, an interlayer insulation film layer 4 covering the first wiring layer 3, and a second wiring layer 5 formed on the interlayer insulation film layer 4.

Referring to FIGS. 2A and 2B, wires 3a and 3b, which are made of aluminum, are formed in the first wiring layer 3. Photolithography, which is known in the art, is performed to form box-shaped dummy conductive pieces 3D between the wires 3a and 3b. The dummy conductive pieces 3D are made of the same material as the wires 3a and 3b. More specifically, the wires 3a and 3b are generally parallel to each other. The dummy conductive pieces 3D each have sides that are inclined by approximately 45° relative to the wires 3a and 3b. Further, the dummy conductive pieces 3D are formed at generally equal intervals in the vertical direction as viewed in FIG. 2A and are slightly deviated from one another in the horizontal direction as viewed in FIG. 2A. The interval between adjacent dummy conductive pieces 3D in the vertical direction is preferably 0.1 to 10 μm, and more preferably 0.1 to 2 μm. The deviated distance of adjacent dummy conductive pieces 3D in the horizontal direction is preferably approximately half the dimension of each dummy conductive piece 3D in the horizontal direction.

The interlayer insulation film layer 4 includes an interlayer insulation film 4a, which is formed from a plasma-tetra-ethoxy-silane (p-TEOS) film, an interlayer insulation film 4b, which has superior flatness and is formed from a spin-on glass (SOG) film on the interlayer insulation film 4a, and an interlayer insulation film 4c, which is formed from a p-TEOS film on the interlayer insulation film 4b. The second wiring layer 5, which includes a wire 5a made of aluminum, is formed on the interlayer insulation film 4c. Each of the dummy conductive pieces 3D is arranged so that a portion opposing an adjacent one of the wires 5a has a relatively small area.

In this manner, the dummy conductive pieces 3D fill the gaps formed between the wires 3a and 3b so that the upper surface of the interlayer insulation film 4c is flat when the interlayer insulation films 4a to 4c are formed on the first wiring layer 3. Subsequent to the formation of the interlayer insulation films 4a to 4c, when the interlayer insulation film 4c is further flattened by performing, for example, CMP, the dummy conductive pieces 3D reduce local concentration of load. Thus, the dummy conductive pieces 3D prevent the flatness from decreasing due to load concentration. The increase in the flatness of the interlayer insulation film 4c, which is the base of the second wiring layer 5, suppresses the occurrence of wire breakage.

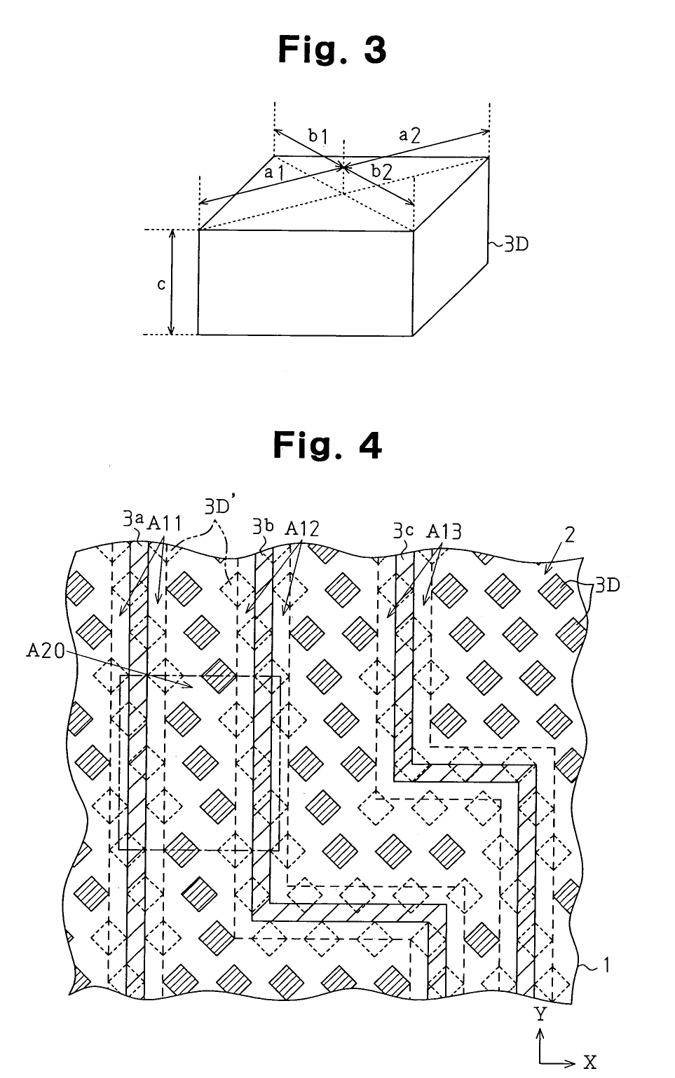

Referring to FIG. 3, the shape and dimensions of the dummy conductive pieces 3D used in the preferred embodiment will now be discussed. FIG. 3 is a perspective view showing a dummy conductive piece 3D, which is inclined toward the left or toward the right by 45°.

In FIG. 3, symbols a1, a2, b1, and b2 each represent one half the length of diagonal lines, and c represents the height of the dummy conductive piece 3D. The dimensions of the dummy conductive piece 3D is determined so that a1, a2, b1, and b2 are all 0.4 μm and so that c is 0.32 μm to 1.0 μm. The wires 3a and 3b, which are shown in FIGS. 2A and 2B, have, for example, a width of 0.4 μm and a thickness (height) of 0.32 to 1.0 μm.

FIG. 4 schematically shows an example of the layout of the first wiring layer 3, which includes the wires 3a and 3b and the dummy conductive pieces 3D. FIG. 2A is an enlarged plan view showing a square section 20A, which is encompassed by broken lines in FIG. 4.

Referring to FIG. 4, the procedures described below are taken to design the layout of the first wiring layer 3.

(I) A predetermined number of dummy conductive pieces 3D are laid out on a substrate that does not include wires. The dummy conductive pieces 3D are laid out at equal intervals in the vertical direction (Y-axis direction) and deviated from one another in the horizontal direction (X-axis direction). In this state, the sides of each dummy conductive piece 3D are inclined relative to the vertical direction by 45°.

(II) Then, wires 3a to 3c are laid out on the substrate in, for example, the X-axis direction or the Y-axis direction.

(III) Dummy conductive pieces 3D′ (indicated by broken lines in FIG. 4) overlapping the wires 3a, 3b, and 3c and the surrounding regions A11 to A13 (indicated by broken lines in FIG. 4) are eliminated.

The above procedures are performed so that at least one dummy conductive piece 3D is arranged between wires that are separated from each other by a predetermined distance. Further, the dummy conductive pieces 3D are box-shaped. This facilitates the layout design and subsequent processing, such as etching.

In the preferred embodiment, the dummy conductive pieces 3D are box-shaped and have sides that are inclined by approximately 45° relative to wires extending along the X-axis and Y-axis directions, as viewed in FIGS. 2A and 4. Thus, when a dummy conductive piece 3D is located adjacent to a wire with a certain distance therebetween, the opposing capacitance (parasitic capacitance) produced between the dummy conductive piece 3D and the adjacent wire is less compared to when a dummy conductive piece is laid out so that its sides are parallel to an adjacent wire (refer to FIG. 1A). The opposing capacitance (parasitic capacitance) between dummy conductive pieces 3D are also decreased. This consequently decreases the parasitic capacitance produced between wires by the dummy conductive pieces 3D.

Although not shown in the drawings, to fabricate the semiconductor integrated circuit device, when cutting out a chip from a wafer, that is, when performing a dicing process, the wafer is cut along the X-axis direction or the Y-axis direction of FIG. 4. Thus, the sides of the dummy conductive pieces 3b are all inclined by approximately 45° relative to the side surfaces of the semiconductor substrate, which is cut out as a chip. In the same manner as the wires 3a to 3c shown in FIG. 4, wires are often laid out parallel to or perpendicular to the side surfaces of the semiconductor substrate that is cut out as a chip. In other words, most of the wires are not parallel to all sides of the dummy conductive pieces 3D.

In FIG. 2A, the portion of a wire 5 overlapped with an adjacent one of the dummy conductive pieces 3D has a relatively small area. In other words, each dummy conductive piece 3D is shaped so that the portion opposing an adjacent one of the wires 5a has a relatively small area. Accordingly, the parasitic capacitance produced between the dummy conductive piece 3D and the wire 5a is relatively small.

The semiconductor integrated circuit device of the preferred embodiment has the advantages described below.

(1) The dummy conductive pieces 3D, which flatten layers arranged between wiring layers, are box-shaped and include sides that are inclined relative to adjacent wires by approximately 45°. Accordingly, when a dummy conductive piece 3D is located adjacent to a wire with a certain distance therebetween, the opposing capacitance (parasitic capacitance) produced between the dummy conductive piece 3D and the adjacent wire is less compared to when a dummy conductive piece is laid out so that its sides are parallel to an adjacent wire. Parasitic capacitance would decrease the operation speed of the circuit and increase noise. However, in the semiconductor integrated circuit device of the preferred embodiment, the dummy conductive pieces 3D increase the flatness of a base for an upper layer, while preventing noise form increasing and the operation speed of the circuit form decreasing.

(2) The sides of the dummy conductive pieces 3D are inclined by approximately 45° relative to the side surfaces of the semiconductor substrate that is cut out as a chip. Thus, in most of the wires, the opposing capacitance (parasitic capacitance) produced between wires and dummy conductive pieces are reduced.

It should be apparent to those skilled in the art that the present invention may be embodied in many other specific forms without departing from the spirit or scope of the invention. Particularly, it should be understood that the present invention may be embodied in the following forms.

In the preferred embodiment, the interlayer insulation film layer 4 includes the three interlayer insulation films 4a to 4c, which are made of the materials described above. However, the configuration and the material of the interlayer insulation film layer 4 are not limited. For example, the interlayer insulation film layer 4 may be configured from a single layer.

In the preferred embodiment, the dummy conductive pieces 3D are laid out at generally equal intervals in the vertical direction and deviated from one another in the horizontal direction between the wires 3a and 3b. However, the dummy conductive pieces 3D may be laid out in any manner. For example, the dummy conductive pieces 3D may be laid out in both vertical and horizontal directions.

The angle of the sides of the dummy conductive pieces 3D relative to adjacent wires does not have to be 45°. For example, the angle of the sides of the dummy conductive pieces 3D relative to the adjacent wires may be 30° to 60°, preferably, 35° to 55°, and more preferably, 40° to 50°.

In the preferred embodiment, the dummy conductive piece 3D is box-shaped and has four sides inclined by approximately 45° relative to the adjacent wires and the side surface of the semiconductor substrate, which is cut out as a chip. However, the dummy conductive pieces 3D may be shaped as described below.

(a) The dummy conductive piece 3D may be a polygonal prism including at least one side opposed to an adjacent wire that is not parallel to the adjacent wire.

(b) The dummy conductive piece 3D may be a polygonal prism including sides opposed to adjacent wires, all of which are not parallel to the adjacent wires.

(c) The dummy conductive piece 3D may be a polygonal prism including a side opposed to an adjacent wire in which the distance between the side and the adjacent wire changes intermittently or continuously.

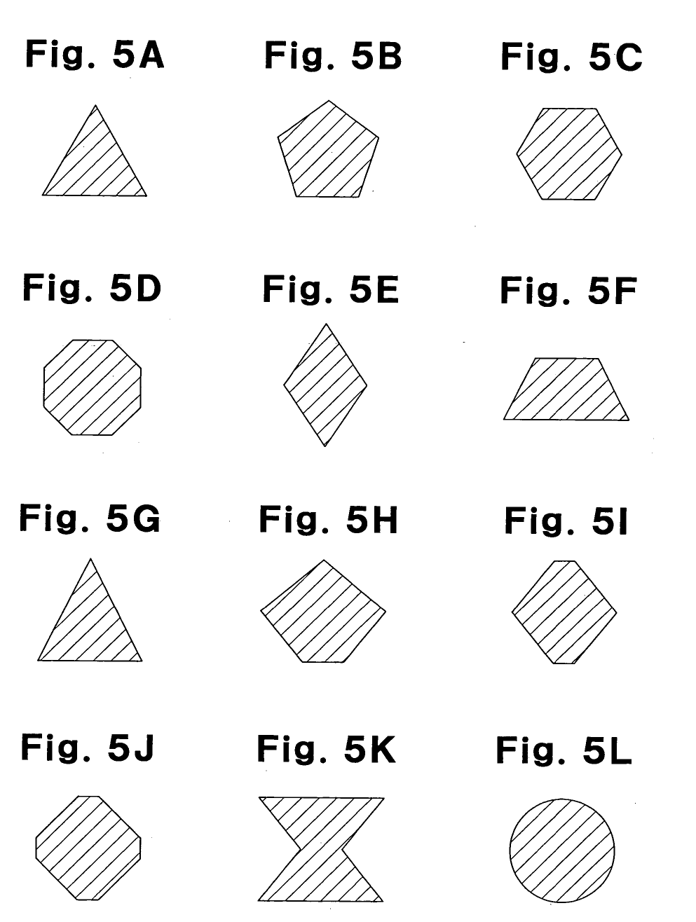

Further, the dummy conductive piece 3D may be generally cylindrical and include a side opposed to an adjacent wire in which the distance between the side and the adjacent wire changes continuously. In this case, the dummy conductive piece 3D includes a curved side and the bottom surface of the dummy conductive piece 3D may be elliptic or semicircular. The dummy conductive piece 3D may be a polygonal prism or be cylindrical and have a bottom surface shaped as shown in, for example, FIGS. 5A to 5L. The dummy conductive piece 3D may a polygonal prism in which the distance between the opposing sides of the dummy conductive piece 3D changes intermittently or continuously. In this case, with respect to the wires on opposite sides of the dummy conductive piece 3D, the opposing capacitance (parasitic capacitance) produced between the dummy conductive piece 3D and the adjacent wire is reduced. When the dummy conductive piece 3D is generally cylindrical as shown in FIG. 5L so that the distance between its cylindrical side and the opposing wire changes continuously, the opposing capacitance (parasitic capacitance) produced between the dummy conductive piece 3D and the opposing wire, which may extend in any direction, is reduced. In the present invention, it is only required that the dummy conductive piece be shaped so that the opposing capacitance produced between the dummy conductive piece and the adjacent wire is reduced in comparison to a box-shaped dummy conductive piece having sides that are parallel to the wires.

The material of the wires and the dummy conductive pieces formed in the wiring layer is not restricted to aluminum. For example, copper, aluminum alloy, or polycrystalline silicon may be used as the material of the wires and the dummy conductive pieces. Further, the dimensions of each dummy conductive piece are not restricted and may be determined in accordance with the width of the wires formed in the wiring layer.

The present examples and embodiments are to be considered as illustrative and not restrictive, and the invention is not to be limited to the details given herein, but may be modified within the scope and equivalence of the appended claims.

1. A semiconductor integrated circuit device comprising:
a semiconductor substrate;
a plurality of wires formed on the semiconductor substrate with a predetermined distance therebetween;
a dummy conductive piece formed between the wires, with the dummy conductive piece shaped to reduce capacitance produced between the dummy conductive piece and an adjacent one of the wires.

2. The semiconductor integrated circuit device according to claim 1, wherein the dummy conductive piece is a polygonal prism having a side opposing the adjacent one of the wires that is not parallel to the adjacent one of the wires.

3. The semiconductor integrated circuit device according to claim 2, wherein the dummy conductive piece has a side inclined by an angle of 45° relative to the adjacent one of the wires.

4. The semiconductor integrated circuit device according to claim 1, wherein the dummy conductive piece is a polygonal prism having a side opposed to the adjacent one of the wires, wherein the distance between the side and the adjacent one of the wires changes intermittently or continuously.

5. The semiconductor integrated circuit device according to claim 1, wherein the dummy conductive piece is generally cylindrical and has a side opposed to the adjacent one of the wires, wherein the distance between the side and the adjacent one of the wires changes continuously.

6. A semiconductor integrated circuit device including a side surface formed when cut out as a chip, the device comprising:
a semiconductor substrate;
a plurality of wires formed on the semiconductor substrate with a predetermined distance therebetween; and
a dummy conductive piece formed between the wires, with the dummy conductive piece being box-shaped and including four sides that are not parallel to the side surface of the semiconductor substrate.

7. A semiconductor integrated circuit device comprising:
a semiconductor substrate;
a plurality of wires formed on the semiconductor substrate with a predetermined distance therebetween; and
a plurality of dummy conductive pieces formed between the wires, with the dummy conductive pieces being polygonal prisms including opposing sides, wherein the distance between the opposing sides changes intermittently or continuously.

8. A semiconductor integrated circuit device comprising:
a semiconductor substrate;
a plurality of wires formed on the semiconductor substrate with a predetermined distance therebetween; and
a dummy conductive piece formed between the wires, with the dummy conductive piece being generally cylindrical.

9. A semiconductor integrated circuit device comprising:
a semiconductor substrate;
a plurality of wires formed on the semiconductor substrate with a predetermined distance therebetween; and
a dummy conductive piece formed between the wires, the dummy conductive piece being a polygonal prism including a plurality of sides, wherein the side closest to one of the wires is not parallel to the one of the wires.

10. A semiconductor integrated circuit device comprising:
a semiconductor substrate;
a plurality of wires formed on the semiconductor substrate with a predetermined distance therebetween; and
a dummy conductive piece formed between the wires, with the dummy conductive piece being shaped so that a portion opposing an adjacent one of the wires has a reduced area.

11. A semiconductor integrated circuit device comprising:
a semiconductor substrate;
a plurality of first wires formed on the semiconductor substrate with a predetermined distance therebetween;
a dummy conductive piece formed between the first wires;
an insulation film covering the first wires and the dummy conductive piece; and
a plurality of second wires formed on the insulation film, with the dummy conductive piece shaped to reduce capacitance between the dummy conductive piece and an adjacent one of the second wires.

12. A semiconductor integrated circuit device comprising:
a semiconductor substrate;
a plurality of first wires formed on the semiconductor substrate with a predetermined distance therebetween;
a dummy conductive piece formed between the first wires;
an insulation film covering the first wires and the dummy conductive piece; and
a plurality of second wires formed on the insulation film, with the dummy conductive piece being shaped so that a portion opposing an adjacent one of the second wires has a reduced area.
